(19) United States
(12) Patent Application Publication
(10) Pub. No.: US 2021/0255796 A1
(43) Pub. Date: Aug. 19, 2021

(54) MEMORY SYSTEM AND METHOD OF CONTROLLING NONVOLATILE MEMORY

(71) Applicant: Kioxia Corporation, Tokyo (JP)

(72) Inventor: Takayuki Takano, Yokohama (JP)

(73) Assignee: Kioxia Corporation, Tokyo (JP)

(21) Appl. No.: 17/020,338

(22) Filed: Sep. 14, 2020

(30) Foreign Application Priority Data
Feb. 17, 2020 (JP) 2020-024285

(51) Int. Cl. G06F 3/06

(52) U.S. Cl. CPC G06F 3/0655; G06F 3/0604; G06F 3/0679

(57) ABSTRACT

According to one embodiment, a memory system includes a plurality of nonvolatile memory chips and a controller configured to control the nonvolatile memory chips through a channel. The controller detects a program command sequence and sets a second chip enable signal corresponding to a second nonvolatile memory chip of the nonvolatile memory chips to the enable state during a period of at least data input cycle in the detected program command sequence. The controller transmits, when it is indicated that a ready/busy signal input to the controller while the second chip enable signal is in the enable state, a command sequence to the second nonvolatile memory chip.

### CROSS-REFERENCE TO RELATED APPLICATIONS

This application is based upon and claims the benefit of priority from Japanese Patent Application No. 2020-024285, filed Feb. 17, 2020, the entire contents of which are incorporated herein by reference.

### FIELD

Embodiments described herein relate generally to technology of controlling a nonvolatile memory.

### BACKGROUND

Recently, storage devices which control nonvolatile memories are widely used.

As such the storage devices, a solid state drive (SSD) including a NAND flash memory is known. The SSD is used in various types of computers.

For the SSD, there is demand of improving a performance in regard to writing of data and reading of data. Therefore, implement of a new technique capable of improving the performance of the SSD is required.

### BRIEF DESCRIPTION OF THE DRAWINGS

FIG. 1 is a block diagram is illustrating a configuration example of a storage system including a memory system according to an embodiment.

FIG. 2 is a diagram illustrating a relationship of connection between a nonvolatile memory control circuit and a plurality of nonvolatile memory chips, which are included in the memory system of the embodiment.

FIG. 3 is a diagram illustrating a relationship of connection between a plurality of nonvolatile memory chips connected to the same channel and the nonvolatile memory control circuit.

FIG. 4 is a block diagram illustrating a configuration example of a status determining circuit included in the nonvolatile memory control circuit.

FIG. 5 is a timing chart illustrating a ready/busy signal output function of each of the nonvolatile memory chips.

FIG. 6 is a timing chart illustrating a status read operation.

FIG. 7 is a timing chart illustrating an operation of determining whether a check target nonvolatile memory chip is in a ready status or busy status by asserting a chip enable signal of the check target nonvolatile memory chip during a period of a data input cycle.

FIG. 8 is a timing chart illustrating a status read operation to be executed when it has not been confirmed that the check target nonvolatile memory chip is in the ready status during the period of the data input cycle.

FIG. 9 is a timing chart illustrating an operation of determining whether each of a plurality of nonvolatile memory chips is in the ready status or the busy status during the period of the data input cycle by alternately asserting chip enable signals of the nonvolatile memory chips during the period of the data input cycle.

FIG. 10 is a flow chart illustrating a procedure of a process of determining the ready/busy status of a check target nonvolatile memory chip by asserting a chip enable signal of the check target nonvolatile memory chip during the period of the data input cycle.

FIG. 11 is a flow chart illustrating a procedure of a process of determining whether each of a plurality of nonvolatile memory chips is in the ready status or busy status by alternately asserting chip enable signals of the plurality of nonvolatile memory chips during the period of the data input cycle.

### DETAILED DESCRIPTION

Various embodiments will be described hereinafter with reference to the accompanying drawings.

In general, according to one embodiment, a memory system comprises a plurality of nonvolatile memory chip and a controller configured to control the plurality of nonvolatile memory chips via a channel. The controller has a first terminal commonly connected to a plurality of ready/busy signal terminals of the plurality of nonvolatile memory chips and a plurality of second terminals which supply a plurality of chip enable signals to the plurality of nonvolatile memory chips, respectively. Each of the plurality of nonvolatile memory chips is configured to output a ready/busy signal only in a period in which a corresponding chip enable signal is in an enable state.

The controller transmits a program command sequence to write data to a first nonvolatile memory chip of the plurality of nonvolatile memory chips to the first nonvolatile memory chip via the channel. The controller detects the program command sequence and sets, while maintaining a first chip enable signal corresponding to the first nonvolatile memory chip in an enable state, a second chip enable signal corresponding to a second nonvolatile memory chip of the plurality of nonvolatile memory chips to an enable state during a period of at least a data input cycle of the detected program command sequence. When it is indicated that a ready/busy signal input to the first terminal is in a ready status while the second chip enable signal is in the enable state, the controller transmits a command sequence for the second nonvolatile memory chip to the second nonvolatile memory chip via the channel in response to end of the transmission of the program command sequence.

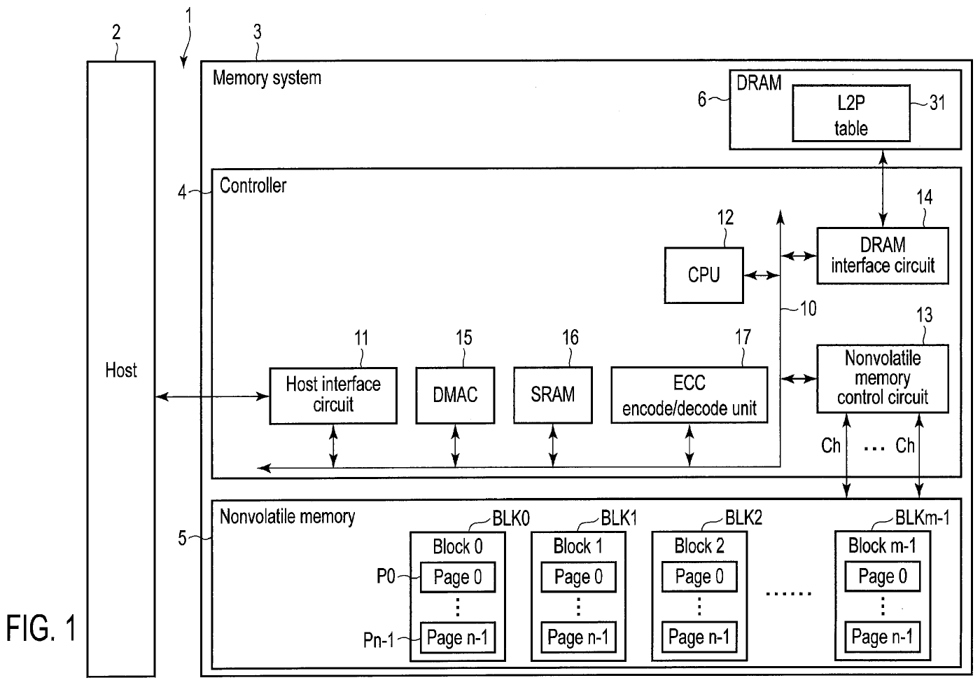

First, a structure of a memory system of an embodiment will be described. FIG. 1 is block diagram illustrating a configuration example of a storage system 1 including a memory system 3 of the embodiment.

The storage system 1 includes a host (host device) 2 and the memory system 3. The host 2 transmits a write command for writing data and a read command for reading data to the memory system 3. The host 2 is an information processing apparatus for controlling the operation of the memory system 3. The information processing apparatus may be a personal computer, a server computer, a mobile terminal or a vehicle-mounted device.

The memory system 3 is a semiconductor storage device configured to write data to a nonvolatile memory and to read data from the nonvolatile memory. The memory system 3 may be built in the information processing apparatus functioning as the host 2 or may be connected to the information processing apparatus via a cable or network. The memory system 3 may be realized as, for example, an SSD including a NAND flash memory.

The memory system 3 includes a controller 4 and a nonvolatile memory 5. The memory system 3 may further include a random-access memory (RAM), that is, for example, a dynamic RAM (DRAM) 6.

The nonvolatile memory 5 includes a memory cell array including a plurality of memory cells arranged in a matrix. The memory cell array of the nonvolatile memory 5 includes a plurality of blocks BLK0 to BLKm-1. Each of the blocks BLK0 to BLKm-1 functions as an erase unit. Each of the blocks BLK0 to BLKm-1 includes a plurality of pages (here, pages P0 to Pn-1). Each of the pages includes a plurality of memory cells connected to the same word line. The pages P0 to Pn-1 are units for a data write operation and a data read operation.

The nonvolatile memory 5 is, for example, a NAND flash memory. The nonvolatile memory 5 may be implemented as a two-dimensionally structured NAND flash memory or a three-dimensionally structured NAND flash memory.

The controller 4 is electrically connected to the nonvolatile memory 5. The controller 4 operates as a memory controller configured to control the nonvolatile memory 5. The controller 4 may be realized by a circuit such as a system-on-a-chip (SoC).

The controller 4 includes a host interface circuit 11, a CPU 12, a nonvolatile memory control circuit 13, a dynamic RAM interface circuit (DRAM interface circuit) 14, a direct memory access controller (DMAC) 15, a static RAM (SRAM) 16 and an ECC encode/decode unit 17.

The host interface circuit 11, CPU 12, nonvolatile memory control circuit 13, DRAM interface circuit 14, DMAC 15, SRAM 16, ECC encode/decode unit 17 are connected to a bus 10.

The host interface circuit 11 is configured to execute communications with the host 2. The host interface 11 receives various requests from the host 2. These requests include a write request to write data to the nonvolatile memory 5 of the memory system 3, a read request to read data from the nonvolatile memory 5 of the memory system 3, and other various requests.

The CPU 12 is a processor configured to control the host interface circuit 11, nonvolatile memory control circuit 13, DRAM interface circuit 14, DMAC 15, SRAM 16, and ECC encode/decode unit 17. The CPU 12 executes various processes by executing a control program (firmware). The CPU 12, in response to supply of power to the memory system 3, loads the firmware from a ROM (not shown) or the nonvolatile memory 5 into the SRAM 16 or DRAM 6. The CPU 12 executes various processes by executing the firmware.

The CPU 12 can function as a flash translation layer (FTL) configured to execute management of data stored in the nonvolatile memory 5 and management of blocks in the nonvolatile memory 5. The data management by the FTL includes management of mapping information indicating the corresponding relation between each of logical addresses and each of physical addresses. The logical addresses each are an address used by the host 2 to designate an address of a location in a logical address space. A physical address corresponding to a certain logical address indicates a physical storage location in the nonvolatile memory 5, at where data corresponding to the logical address is written. As a logical address, generally, a logical block address (addressing) (LBA) can be used.

The CPU 12 manages the corresponding relation between each logical address and each physical address using a logical-to-physical address translation table (L2P table) 31.

The nonvolatile memory control circuit 13 is a memory control circuit configured to control the nonvolatile memory 5 under the control of the CPU 12. In the memory system 3, a plurality of nonvolatile memory chips are usually mounted as the nonvolatile memory 5. The nonvolatile memory control circuit 13 is configured to control these nonvolatile memory chips. The nonvolatile memory control circuit 13 may be connected to, for example, a plurality of nonvolatile memory chips via a plurality of channels (Ch).

Usually, a plurality of nonvolatile memory chips are connected to one channel. The nonvolatile memory control circuit 13 can operate the plurality of nonvolatile memory chips connected to the same channel in parallel. As an example of the method of making the plurality of nonvolatile memory chips operate in parallel, an interleave operation (also referred to as a bank interleave) may be employed. In the interleave operation (bank interleave), for example, a plurality of nonvolatile memory chips are classified into a plurality of banks, and while a nonvolatile memory chip corresponding to a certain bank is executing a write, read or erase operation, access to a nonvolatile memory chip corresponding to another bank is started. Here, a bank is a unit for making a plurality of memory modules in parallel by bank interleaving. Note that a nonvolatile memory chip is also referred to as a nonvolatile memory die.

The DRAM interface 14 is a DRAM control circuit configured to control the DRAM 6 under the control of the CPU 12. A part of the memory area of the DRAM 6 may be used to store the L2P table 31.

The DMAC 15 executes data transfer between a memory of the host 2 and the SRAM 16 (or the DRAM 6) under the control of the CPU 12.

A part the memory area of the SRAM 16 or a part of the memory area of the DRAM 6 may be used as a write buffer to temporarily store data to be written to the nonvolatile memory 5.

When data is to be written to the NAND flash memory 5, the ECC encode/decode unit 17 encodes the data (data to be written) (ECC encoding), thereby adding an error correction code (ECC) to the data as a redundant code. When data is read from the NAND flash memory 5, the ECC encoding/decoding unit 17 executes error correction of the read data (ECC decoding) by using the ECC added to the read data.

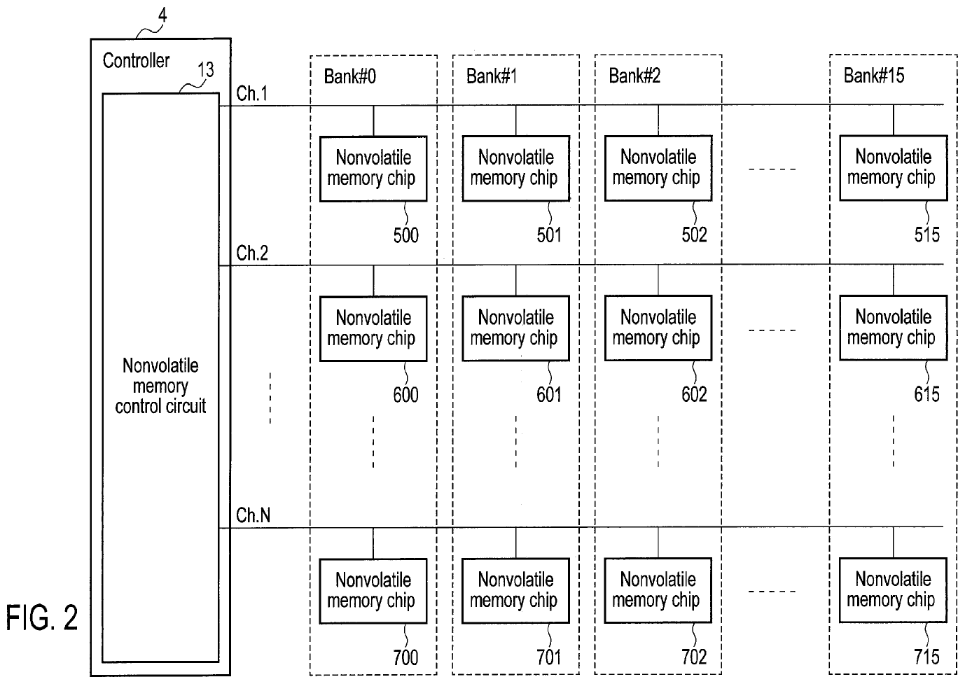

FIG. 2 is a diagram illustrating a relation of connection between the nonvolatile memory control circuit 13 and a plurality of nonvolatile memory chips, which are included in the memory system 3. FIG. 2 illustrates an example case that the nonvolatile memory control circuit 13 is connected to a plurality of nonvolatile memory chips via N channels (Ch.1 to Ch.N).

For example, a nonvolatile memory chip 500, a nonvolatile memory chip 501, a nonvolatile memory chip 502, . . . , a nonvolatile memory chip 515 are connected to the channel Ch.1, and a nonvolatile memory chip 600, a nonvolatile memory chip 601, a nonvolatile memory chip 602, . . . , a nonvolatile memory chip 615 are connected to the channel Ch.2. Similarly, a nonvolatile memory chip 700, a nonvolatile memory chip 701, a nonvolatile memory chip 702, . . . , a nonvolatile memory chip 715 are connected to the channel Ch.N.

The nonvolatile memory chips 500, 600, . . . , 700, respectively connected to the channels Ch.1 to Ch.N may be organized as a bank #0. Similarly, the nonvolatile memory chips 501, 601, . . . , 701, respectively connected to the channels Ch.1 to Ch.N are organized as a bank #1. The nonvolatile memory chips 502, 602, . . . , 702, respectively connected to the channels Ch.1 to Ch.N may be organized as a bank #2. Similarly, the nonvolatile memory chips 515, 615, . . . , 715, respectively connected to the channels Ch.1 to Ch.N may be organized as a bank #15.

In the example of the connection shown in FIG. 2, a maximum of sixteen nonvolatile memory chips per one channel can be made to operate in parallel by the bank interleaving using sixteen banks. Note that it suffices if the number of banks per one channel is two or more.

Note that N is generally an integer of 2 or more, but in principle, a configuration of N=1 may be used.

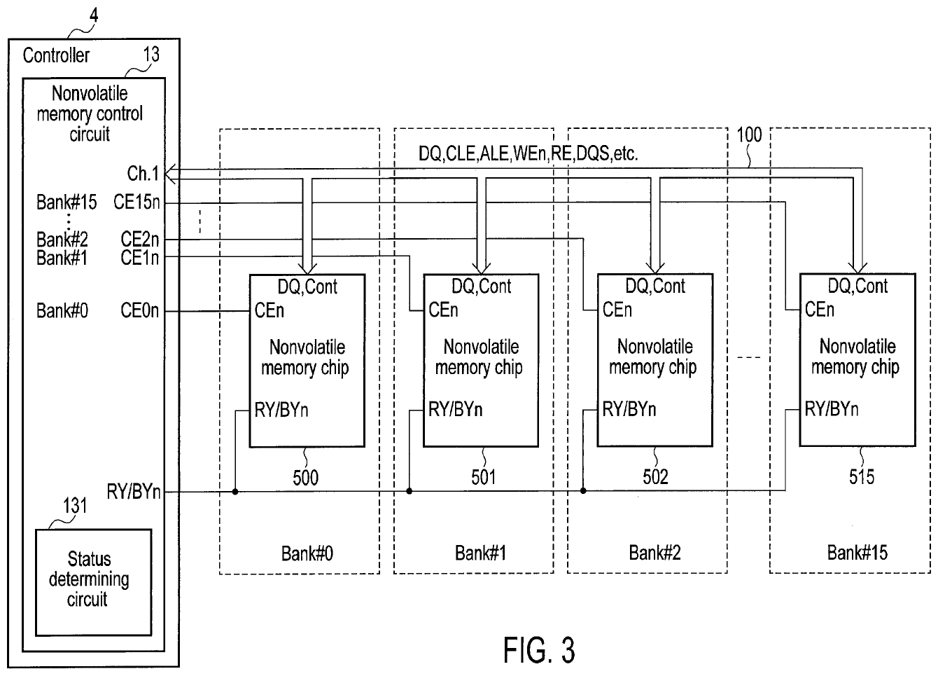

FIG. 3 is a diagram illustrating the relationship of connection between a plurality of nonvolatile memory chips connected to the same channel and the nonvolatile memory control circuit 13.

FIG. 3 illustrates an example case where the relation of connection between the nonvolatile memory chips connected to the channel Ch.1 and the nonvolatile memory control circuit 13.

A memory bus 100 included in the channel Ch.1 includes a data bus having a width of a plurality of (for example, 8) bits. The data bus is used to transfer DQ signals in multiple bit units. In the following description, for example, the data bus has a 8-bit width, and it is assumed that 8-bit DQ signals are transferred via the data bus. The memory bus 100 further includes a plurality of signal lines to carry a plurality of signals (a command latch enable signal CLE, an address latch enable signal ALE, a write enable signal WEn, a read enable signal REn, a data strobe signal DQS and the like), respectively. Here, the symbol “n” attached to the end of the name of signals means that each of these signals is an active low signal.

The 8-bit DQ signals are used to transfer a command, an address, and data. The command latch enable signal CLE is a signal indicating that a current cycle on the data bus is a command cycle. The address latch enable signal ALE is a signal indicating that a current cycle on the data bus is an address cycle. The write enable signal WEn is a signal which controls acquisition (latching) of a command or an address from the data bus. The read enable signal REn is a signal which controls the data output to the data bus. The data strobe signal DQS is a signal which controls acquisition (latching) of data from the data bus.

Let us assume the case of, for example, executing a program command sequence to write data to a certain nonvolatile memory chip. The nonvolatile memory control circuit 13 sets a chip enable signal corresponding to the nonvolatile memory chip to an active state and outputs a program command sequence including a program command (for example, 80h), an address, data, and a program command (for example, 10h) to the data bus. The two program commands (80h and 10h) are used to input the data to the nonvolatile memory chip and to write the input data to the nonvolatile memory chip.

In this case, first, the nonvolatile memory control circuit 13 sets the command latch enable signal CLE to an active state, outputs the program command (e.g., 80h) to the data bus and sets the write enable signal WEn to an active state. When the write enable signal WEn is set to the active state while the command latch enable signal CLE is in the active state, the nonvolatile memory chip latches the 8-bit DQ signal on the data bus as a command (here, a program command (for example, 80h)).

The nonvolatile memory control circuit 13 sets the address latch enable signal ALE to the active state, outputs an address (for example, a column address, a page address or the like) to the data bus, and sets the write enable signal WEn to the active state each time an address is output. Each time the write enable signal WEn is set to the active state while the address latch enable signal ALE is in the active state, the nonvolatile memory chip latches the current 8-bit DQ signal on the data bus as the address.

Then, the nonvolatile memory control circuit 13 executes the data input cycle. Here, the nonvolatile memory control circuit 13 repeatedly executes the cycle to output write data to the data bus, and switches the data strobe signal DQS between a high level and a low level alternately (toggling) each time the data input cycle repeats. The nonvolatile memory chip latches the current 8-bit DQ signal [7:0] on the data bus as the write data for one byte each time the level of the data strobe signal DQS is changed. As a result of the data input cycle, for example, data for one page are input to the nonvolatile memory chip.

The nonvolatile memory control circuit 13 sets the command latch enable signal CLE to the active state, outputs a program command (for example, 10h) to the data bus, and sets the write enable signal WEn to the active state. When the write enable signal WEn is set to the active state while the command latch enable signal CLE is in the active state, the nonvolatile memory chip latches the 8-bit DQ signal on the data bus as a command (here, a program command (for example, 10h)). When the nonvolatile memory chip have latched the two program commands (80h and 10h), the nonvolatile memory chip starts the program operation to write the input data to the page designated by the input address.

Note that in the data read operation, the nonvolatile memory chip repeatedly executes the cycle to output read data to the data bus, and also switches (toggles) the data strobe signal DQS between the high level and the low level alternately each time the cycle repeats. The nonvolatile memory control circuit 13 latches the 8-bit DQ signal on the data bus as read data each time the level of the data strobe signal DQS is switched.

The nonvolatile memory control circuit 13 of the controller 4 is connected to each of the nonvolatile memory chip 500, nonvolatile memory chip 501, nonvolatile memory chip 502, . . . , nonvolatile memory chip 515 via the memory bus 100 of the channel Ch.1.

Each of the nonvolatile memory chip 500, nonvolatile memory chip 501, nonvolatile memory chip 502, . . . , nonvolatile memory chip 515 has eight DQ terminals each corresponding to 8-bit width data and a plurality of control terminals. The DQ terminals of each nonvolatile memory chip are terminals used to input and output 8-bit DQ signals and the DQ terminals of each nonvolatile memory chip are connected to data buses (eight DQ signal lines) in the memory bus 100. The control terminals of each nonvolatile memory chip are terminals used for inputting of command latch enable signals CLE, inputting of address latch enable signals ALE, inputting of write enable signals WEn, inputting of read enable signals REn, inputting/outputting of data strobe signals DQS, and the control terminals of each nonvolatile memory chip are connected to the plurality of signal lines in the memory bus 100.

Each of the nonvolatile memory chip 500, nonvolatile memory chip 501, nonvolatile memory chip 502, . . . , nonvolatile memory chip 515 further has a chip enable signal CEn input terminal and a ready/busy signal RY/BYn output terminal.

The nonvolatile memory control circuit 13 of the controller 4 has a plurality of terminals to supply chip enable signal CE0n, chip enable signal CE1n, chip enable signal CE2n, . . . , chip enable signal CE15n to the nonvolatile memory chip 500, nonvolatile memory chip 501, nonvolatile memory chip 502, . . . , nonvolatile memory chip 515, respectively. In FIG. 3, to indicate the corresponding relation between each bank and each chip enable signal, the following representations are used: “Bank #0 CE0n” for the chip enable signal corresponding to the bank #0; “Bank #1 CE1n” for chip enable signal corresponding to the bank #1; “Bank #2 CE2n” for the chip enable signal corresponding to bank #2; and “Bank #15 CE15n” for the chip enable signal corresponding to bank #15.

Each chip enable signal is an active low signal. Each of the chip enable signal CE0n, chip enable signal CE1n, chip enable signal CE2n, . . . , chip enable signal CE15n is a signal for selecting a corresponding nonvolatile memory chip.

Further, the nonvolatile memory control circuit 13 of the controller 4 has one ready/busy signal RY/BYn terminal commonly connected to a plurality of ready/busy signal RY/BYn output terminals respectively corresponding to the nonvolatile memory chip 500, nonvolatile memory chip 501, nonvolatile memory chip 502, . . . , nonvolatile memory chip 515.

The ready/busy signal RY/BYn is an active low signal. When the ready/busy signal RY/BY is at a low level, the ready/busy signal RY/BYn indicates a busy status. Further, the ready/busy signal RY/BYn is an open drain output.

That is, a plurality of ready/busy signal RY/BYn terminals respectively corresponding to the nonvolatile memory chip 500, nonvolatile memory chip 501, nonvolatile memory chip 502, . . . , nonvolatile memory chip 515 are commonly connected, by wired connection, to one ready/busy signal RY/BYn terminal of the nonvolatile memory control circuit 13.

The configuration to connect ready/busy signal RY/BYn terminals of the nonvolatile memory chips by wired connection is employed to reduce the number of ports need to be provided on the controller 4.

In the configuration that ready/busy signal RY/BYn terminals of the nonvolatile memory chips are connected by the wired connection, usually, not a ready/busy signal RY/BYn, but a status read command is used to check the ready/busy status of each nonvolatile memory chip.

A nonvolatile memory chip which has received a status read command via the memory bus 100 of the channel Ch.1 outputs its own status (a ready status or busy status) to the memory bus 100 of the channel Ch.1 as data output.

Here, the ready status indicates a status in which the memory cell array in a nonvolatile memory chip is able to execute the write, read or erase operation. The busy status indicates a status in which the memory cell array in a nonvolatile memory chip is executing the write, read or erase operation so that the write, read or erase operation corresponding to a new command cannot be started.

In the status read operation to check the status (ready or busy status) of the nonvolatile memory chip using a status read command, a command cycle to transfer a status read command to a nonvolatile memory chip and a data output cycle to output the status from the nonvolatile memory chip are executed on the memory bus 100 of the channel Ch.1.

Therefore, if the status read operation is executed frequently, the memory bus 100 of the channel Ch.1 is exclusively occupied by the status read operations for relatively a long time. This may cause degradation in the performance of the memory system 3 in regard to writing of data and reading of data.

The nonvolatile memory control circuit 13 includes a status determining circuit 131 configured to efficiently check the status (ready or busy status) of each nonvolatile memory chip.

The status determining circuit 131 determines whether a nonvolatile memory chip whose status is to be checked is in the ready status or busy status, based on the ready/busy signal RY/BYn input to one ready/busy signal RY/BYn terminal of the nonvolatile memory control circuit 13.

This status check operation is realized by utilizing a function of each nonvolatile memory chip. Each of the nonvolatile memory chips is configured as follows.

Each of the nonvolatile memory chip 500, nonvolatile memory chip 501, nonvolatile memory chip 502, . . . , nonvolatile memory chip 515 is configured to output ready/busy signals RY/BYn during the period in which the corresponding chip enable signal is at an enable state (low level).

In other words, each of the nonvolatile memory chip 500, nonvolatile memory chip 501, nonvolatile memory chip 502, . . . , nonvolatile memory chip 515 does not output ready/busy signals RY/BYn during the period in which the corresponding chip enable signal is at a disable state (high level).

The function of thus outputting ready/busy signals RY/BYn while the corresponding chip enable signal is in the enable state will be referred to also as a “ready/busy signal output function”.

The nonvolatile memory control circuit 13 transmits a program command sequence for writing data to a certain nonvolatile memory chip to the nonvolatile memory chip via the channel Ch.1. The program command sequence includes a first command cycle to transfer a program command (for example, 80h), an address cycle to transfer an address, a data input cycle to transfer data to be written, and a second command cycle to transfer a program command (for example, 10h).

The status determining circuit 131 detects the program command sequence and sets the chip enable signal corresponding to the check target nonvolatile memory chip whose status is to be checked, to the enable state during the period of at least the data input cycle in the detected program command sequence. In this case, the status determining circuit 131 sets the chip enable signal corresponding to the check target nonvolatile memory chip to the enable state, while maintaining the chip enable signal corresponding to the nonvolatile memory chip to which data is to be written in an enable state.

As a result, during the period of at least the data input cycle in the program command sequence, two chip enable signals corresponding to two nonvolatile memory chips (a nonvolatile memory chip to which data is to be written and a check target nonvolatile memory chip whose status is to be checked) are enabled. Therefore, both of the nonvolatile memory chip to which data is to be written and the check target nonvolatile memory chip are able to output ready/busy signals RY/BYn. Under these circumstances, there is a possibility that which of the data-to-be-written nonvolatile memory chip and the check target nonvolatile memory chip is outputting a busy signal (that is, a low-level RY/BYn) cannot be known.

However, it is known that the data-to-be-written nonvolatile memory chip is in the ready status during the period of the program command sequence.

Therefore, during the period in which the chip enable signal corresponding to the check target nonvolatile memory chip whose status is to be checked is set in the enable state, the ready/busy signal RY/BYn input to the nonvolatile memory control circuit 13, more specifically, the ready/busy signal RY/BYn input to one ready/busy signal RY/BYn terminal of the nonvolatile memory control circuit 13, indicates the status of the check target nonvolatile memory chip whose status is to be checked.

As the nonvolatile memory control circuit 13 receives the ready/busy signal RY/BYn input thereto, the nonvolatile memory control circuit 13 can detect that the ready/busy signal RY/BYn is at the high-level, that is, the check target nonvolatile memory chip whose status is to be checked is in the ready status. On the other hand, when the ready/busy signal RY/BYn is at the low level, the nonvolatile memory control circuit 13 can detect that the check target nonvolatile memory chip whose status is to be checked is in the busy status.

Thus, the status determining circuit 131 can determine whether or not a nonvolatile memory chip whose status is to be checked is in the ready status by checking the ready/busy signal RY/BYn input to the nonvolatile memory control circuit 13 during the period in which the chip enable signal corresponding to the check target nonvolatile memory chip is set in the enable state.

Usually, in the program command sequence, the period of the data input cycle is sufficiently longer than the period of the address cycle. In other words, during the period of the data input cycle in the program command sequence, a sufficient time necessary to reliably confirm that the check target nonvolatile memory chip is in the ready status. In order to make it possible to confirm the ready status of the check target nonvolatile memory chip using this period, the status determining circuit 131 may set the chip enable signal corresponding to the check target nonvolatile memory chip to the enable state during the period of the data input cycle in the program command sequence.

In this case, the status determining circuit 131 may detect the start of the data input cycle as a program command sequence. The status determining circuit 131 may detect the start of the data input cycle by, for example, monitoring the data strobe signal DQS which is output to the memory bus of each channel from the nonvolatile memory control circuit 13.

The status determining circuit 131 sets the chip enable signal corresponding to the check target nonvolatile memory chip to the enable state in response to the detection of the start of the data input cycle. Thus, a relatively long period of the data input cycle can be effectively utilized for the status check operation. When the data input cycle is finished, the status determining circuit 131 sets the chip enable signal to the disable state.

The status determining circuit 131 may execute the status check operation only in the period of the data input cycle (case #1). This is because, as set forth above, the data input cycle includes a sufficient time necessary to confirm that the check target nonvolatile memory chip is in the ready status.

Or the status determining circuit 131 may utilize not only the data input cycle included in the program command sequence, but also, for example, a longer period, which corresponds to both the address cycle and the data input cycle which are included in the program command sequence, for the status check operation (case #2).

In the case #2, for example, the status determining circuit 131 may detect the first command cycle (80h) as a program command sequence, and may set the chip enable signal corresponding to the check target nonvolatile memory chip to the enable state in response to the detection of the first command cycle (80h).

When the case #1 is employed, the circuit structure necessary to detect the program command sequence can be simplified and a sufficiently long data input cycle can be effectively utilized.

When the case #2 is employed, the circuit structure necessary to detect the program command sequence is more complicated than in the case #1; however a longer period than that of the case #1 (for example, the address cycle+the data input cycle) can be utilized for the status check operation. Note that, generally, until the chip enable signal is actually set to the enable state from the timing of the detection of the program command sequence, a time lag may occur. Therefore, the configuration to detect the first command cycle (80h) as a program command sequence can be used to optimally utilize the period of the case #1 (that is, the period of the data input cycle).

In the following descriptions, the configuration and operation of the memory system 3 will be discussed with reference to, mainly, the case #1 as an example.

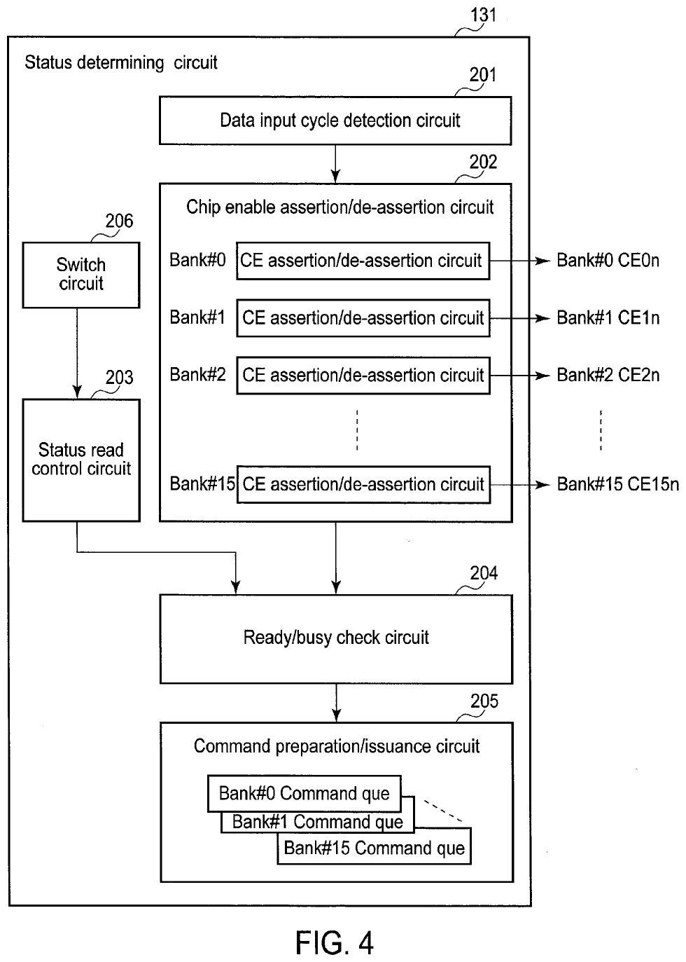

FIG. 4 is a block diagram showing a configuration example of the status determining circuit 131 included in the nonvolatile memory control circuit 13.

The status determining circuit 131 includes a data input cycle detection circuit 201, a chip enable assertion/de-assertion circuit 202, a status read control circuit 203, a ready/busy check circuit 204, a command preparation/issuance circuit 205 and a switch circuit 206.

The data input cycle detection circuit 201 is configured to detect the start of the data input cycle included in the program command sequence as a program command sequence. For example, the data input cycle detection circuit 201 may detect the start of the data input cycle, based on the data strobe signal DQS.

The chip enable assertion/de-assertion circuit 202 asserts and de-asserts the chip enable signal corresponding to the nonvolatile memory chip of an arbitrary bank during the period of the data input cycle. Here, asserting a chip enable signal means to set the chip enable signal to the enable state, and de-asserting a chip enable signal means to set the chip enable signal to the disable state.

The chip enable assertion/de-assertion circuit 202 includes sixteen CE assertion/de-assertion circuits corresponding to the bank #0 to bank #15.

The CE assertion/de-assertion circuit corresponding to the bank #0 controls assertion and de-assertion of a chip enable signal CE0n corresponding to the nonvolatile memory chip 500 belonging to the bank #0 during the period of the data input cycle.

The CE assertion/de-assertion circuit corresponding to the bank #1 controls assertion and de-assertion of a chip enable signal CE1n corresponding to the nonvolatile memory chip 501 belonging to the bank #1 during the period of the data input cycle.

The CE assertion/de-assertion circuit corresponding to bank #2 controls assertion and de-assertion of a chip enable signal CE2n corresponding to the nonvolatile memory chip 502 belonging to the bank #2 during the period of the data input cycle.

Similarly, the CE assertion/de-assertion circuit corresponding to the bank #15 controls assertion and de-assertion of a chip enable signal CE15n corresponding to the nonvolatile memory chip 515 belonging to the bank #15 during the period of the data input cycle included in the program command sequence.

The status read control circuit 203 is configured to transmit the status read command to the check target nonvolatile memory chip. For example, when the check target nonvolatile memory chip is not determined to be in the ready status in the status check operation carried out during the period of the data input cycle, the status read control circuit 203 transmits a status read command to the check target nonvolatile memory chip via the channel Ch.1 in response to the end of the transmission of the program command sequence. Thus, the status of the check target nonvolatile memory chip can be determined once again. In this case, in response to the end of the transmission of the program command sequence, a status check mode needs to be switched to a status check mode which uses the status read control circuit 203 from a status check mode which uses the chip enable assertion/de-assertion circuit 202. To switch the status check mode, a switch circuit 206 may be used. For example, when the check target nonvolatile memory chip is not determined to be in the ready status by the status check operation carried out during the period of the data input cycle, the switch circuit 206 may operate the status read control circuit 203 in response to the end of the transmission of the program command sequence.

The ready/busy checking circuit 204 determines whether or not the check target nonvolatile memory chip is in the ready status by checking the ready/busy signal RY/BYn input to the nonvolatile memory control circuit 13 during the period of the data input cycle. Further, the ready/busy checking circuit 204 also executes the process of determining whether or not the check target nonvolatile memory chip is in the ready status, based on the status acquired by the transmission of the status read command.

The command preparation/issuance circuit 205 prepares a new command sequence for the nonvolatile memory chip determined to be in the ready status, and transmits the already prepared command sequence to the nonvolatile memory chip determined to be in the ready status in response to the end of the transmission of the program command sequence.

The command preparation/issuance circuit 205 may include sixteen command queues corresponding to the bank #0 to bank #15. For example, when the nonvolatile memory chip 501 belonging to the bank #1 is determined to be in the ready status during the period of the data input cycle in the program command sequence for the nonvolatile memory chip 500 belonging to the bank #0, the command sequence to be transmitted to the nonvolatile memory chip 501 is stored in the command queue corresponding to the bank #1. Then, in response to the end of the transmission of the program command sequence to the nonvolatile memory chip 500 belonging to the bank #0, the command sequence is acquired from the command queue corresponding to the bank #1 and is transmitted to the nonvolatile memory chip 501 belonging to the bank #1.

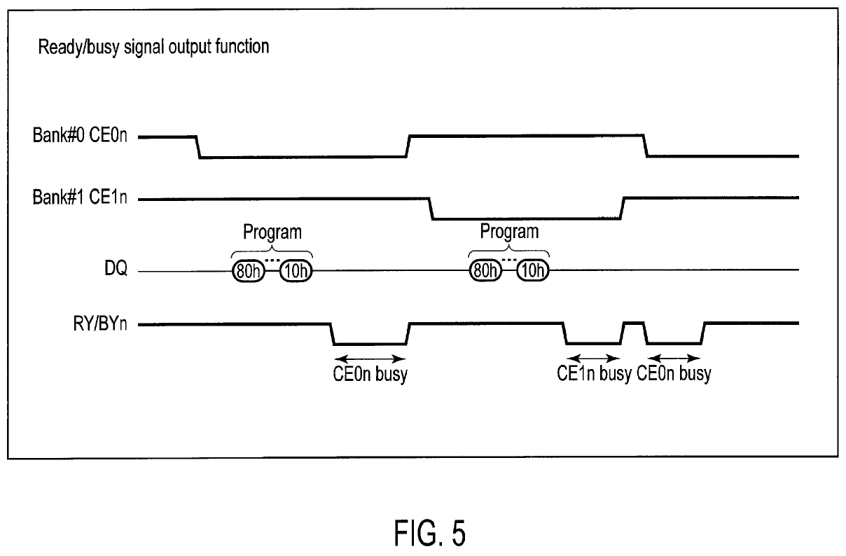

FIG. 5 is a timing chart illustrating the ready/busy signal output function of each nonvolatile memory chip.

In FIG. 5, the chip enable signal CE corresponding to the bank #0 is represented as “Bank #0 CE0n”, the chip enable signal CE corresponding to the bank #1 as “Bank #1 CE1n”.

The nonvolatile memory chip 500 belonging to the bank #0 can output the ready/busy signal only in the period in which the chip enable signal CE0n corresponding to the bank #0 is asserted.

During the period in which the chip enable signal CE0n is asserted, the ready/busy signal RY/BYn input to the nonvolatile memory control circuit 13 indicates the status of the nonvolatile memory chip 500 selected by the chip enable signal CE0n. When the nonvolatile memory chip 500 is in the ready status, the ready/busy signal RY/BYn is at the high-level. After the program command sequences (“80h” and “10h”) is transmitted to the selected nonvolatile memory chip 500, the selected nonvolatile memory chip 500 starts the program operation and the status of the selected nonvolatile memory chip 500 is set in the busy status. In this case, the ready/busy signal RY/BYn input to the nonvolatile memory control circuit 13 changes to the low level. The ready/busy signal RY/BYn at the low level indicates that the selected nonvolatile memory chip 500 is in the busy status.

When the chip enable signal CE0n is de-asserted, the nonvolatile memory chip 500 stops outputting the ready/busy signal. Thus, the ready/busy signal RY/BYn changes to the high level.

When the chip enable signal CE1n is asserted, the ready/busy signal RY/BYn input to the nonvolatile memory control circuit 13 indicates the status of the nonvolatile memory chip 501 selected by the chip enable signal CE1n. When the nonvolatile memory chip 501 is in the ready status, the ready/busy signal RY/BYn is at the high-level. After the program command sequences (“80h” and “10h”) are transmitted to the selected nonvolatile memory chip 501, the selected nonvolatile memory chip 501 starts the program operation and the status of the selected nonvolatile memory chip 501 is set in the busy status. In this case, the ready/busy signal RY/BYn input to the nonvolatile memory control circuit 13 changes to the low level. The ready/busy signal RY/BYn at the low level indicates that the selected nonvolatile memory chip 501 is in the busy status.

When the chip enable signal CE1n is de-asserted, the nonvolatile memory chip 501 stops outputting the ready/busy signal. Thus, the ready/busy signal RY/BYn changes to the high level.

Next, when chip enable signal CE0n is asserted, the ready/busy signal RY/BYn input to the nonvolatile memory control circuit 13 indicates the status of the nonvolatile memory chip 500 selected by the chip enable signal CE0n. If the nonvolatile memory chip 500 continues to execute the program operation, the ready/busy signal RY/BYn input to the nonvolatile memory control circuit 13 changes to the low level.

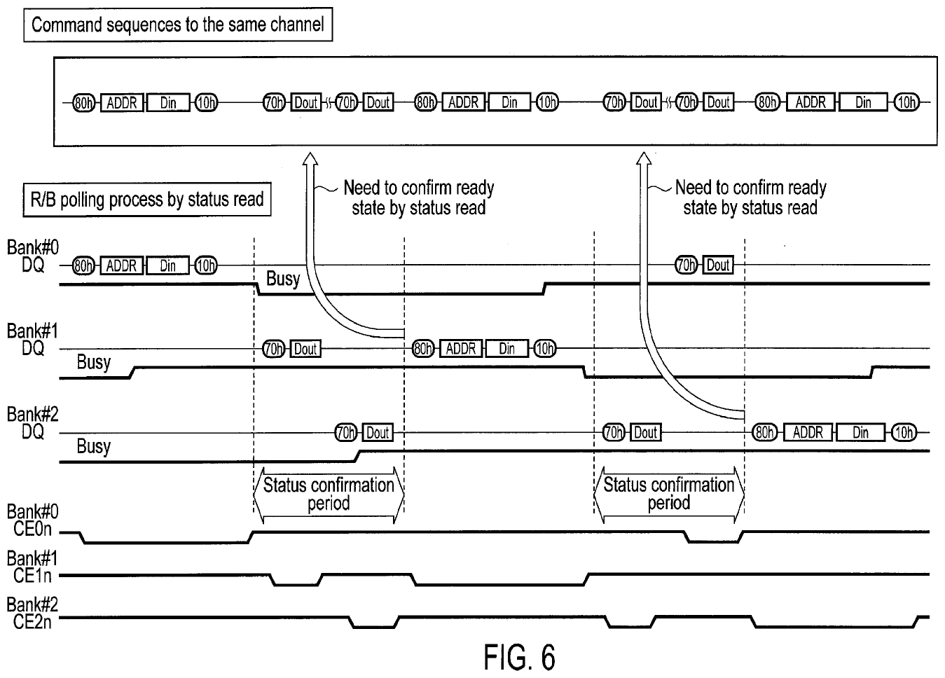

FIG. 6 is a timing chart illustrating the status read operation.

FIG. 6 illustrates an example of the process of checking the statuses of a plurality of nonvolatile memory chips connected to the same channel only by the status read command (that is, an R/B polling process by the status read), without using the status of the ready/busy signal RY/BYn input to the nonvolatile memory control circuit 13.

To make it easy to understand, FIG. 6 illustrates the case on the assumption that three nonvolatile memory chips 500 to 502 corresponding to three banks #0 to #2 are connected to the channel Ch.1. Further, in FIG. 6, each command sequence transmitted to the nonvolatile memory chip 500 of the bank #0 is represented as “Bank #0 DQ”, each command sequence transmitted to the nonvolatile memory chip 501 of the bank #1 is represented as “Bank #1 DQ”, and each command sequences transmitted to the nonvolatile memory chip 502 of the bank #2 as “Bank #2 DQ”. Further, the chip enable signal CE corresponding to the bank #0 is represented as “Bank #0 CE0n”, the chip enable signal CE corresponding to the bank #1 is represented as “Bank #1 CE1n”, and the chip enable signal CE corresponding to the bank #2 is represented as “Bank #2 CE2n”.

First, the chip enable signal CE0n corresponding to the nonvolatile memory chip 500 of the bank #0 is asserted, and the program command sequence (command cycle 80h, address cycle ADDR, data input cycle Din and command cycle 10h) for writing data to the nonvolatile memory chip 500 is transmitted to the nonvolatile memory chip 500 of the bank #0 via the data bus of the channel Ch.1. The nonvolatile memory chip 500 of the bank #0 starts the program operation and is set to the busy status.

After the nonvolatile memory chip 500 of the bank #0 is set to the busy status, the status read operation is started (the status confirmation period).

In the status read operation, first, the chip enable signal CE1n corresponding to the nonvolatile memory chip 501 of the bank #1 is asserted, and the status read command (70h) is transmitted to the nonvolatile memory chip 501 of the bank #1 via the data bus of the channel Ch.1. In response to the reception of the status read command (70h), the nonvolatile memory chip 501 outputs its own status (ready status/busy status) to the data bus as a data output (Dout).

After that, the chip enable signal CE2n corresponding to the nonvolatile memory chip 502 of the bank #2 is asserted, and the status read command (70h) is transmitted to the nonvolatile memory chip 502 of the bank #2 via the data bus of the channel Ch.1. In response to the reception of the status read command (70h), the nonvolatile memory chip 502 outputs its own status (ready status/busy status) to the data bus as a data output (Dout).

If the nonvolatile memory chip 501 of the bank #1 is determined to be in the ready status by the status read operation, the chip enable signal CE1n corresponding to the nonvolatile memory chip 501 of the bank #1 is asserted, and the program command sequence (command cycle 80h, address cycle ADDR, data input cycle Din and command cycle 10h) for writing data to the nonvolatile memory chip 501 is transmitted to the nonvolatile memory chip 501 of the bank #1 via the data bus of the channel Ch.1. The nonvolatile memory chip 501 of the bank #1 starts the program operation and is set to the busy status.

After the nonvolatile memory chip 501 of the bank #1 is set in the busy status, the status read operation is started again (status confirmation period).

In the status read operation, first, the chip enable signal CE2n corresponding to the nonvolatile memory chip 502 of the bank #2 is asserted, and the status read command (70h) is transmitted to the nonvolatile memory chip 502 of the bank #2 via the data bus of the channel Ch.1. In response to the reception of the status read command (70h), the nonvolatile memory chip 502 outputs its own status (ready status/busy status) to the data bus as a data output (Dout).

After that, the chip enable signal CE0n corresponding to the nonvolatile memory chip 500 of the bank #0 is asserted, and the status read command (70h) is transmitted to the nonvolatile memory chip 500 of the bank #0 via the data bus of the channel Ch.1. In response to the reception of the status read command (70h), the nonvolatile memory chip 500 outputs its own status (ready status/busy status) to the data bus as a data output (bout).

If the nonvolatile memory chip 502 of the bank #2 is determined to be in the ready status by the status read operation, the chip enable signal CE2n corresponding to the nonvolatile memory chip 502 of the bank #2 is asserted, and the program command sequence (command cycle 80h, address cycle ADDR, data input cycle Din and command cycle 10h) for writing data to the nonvolatile memory chip 502 is transmitted to the nonvolatile memory chip 502 of the bank #2 via the data bus of the channel Ch.1.

Thus, the data bus of the channel Ch.1 is occupied for a certain period of time for the execution of the status read operation.

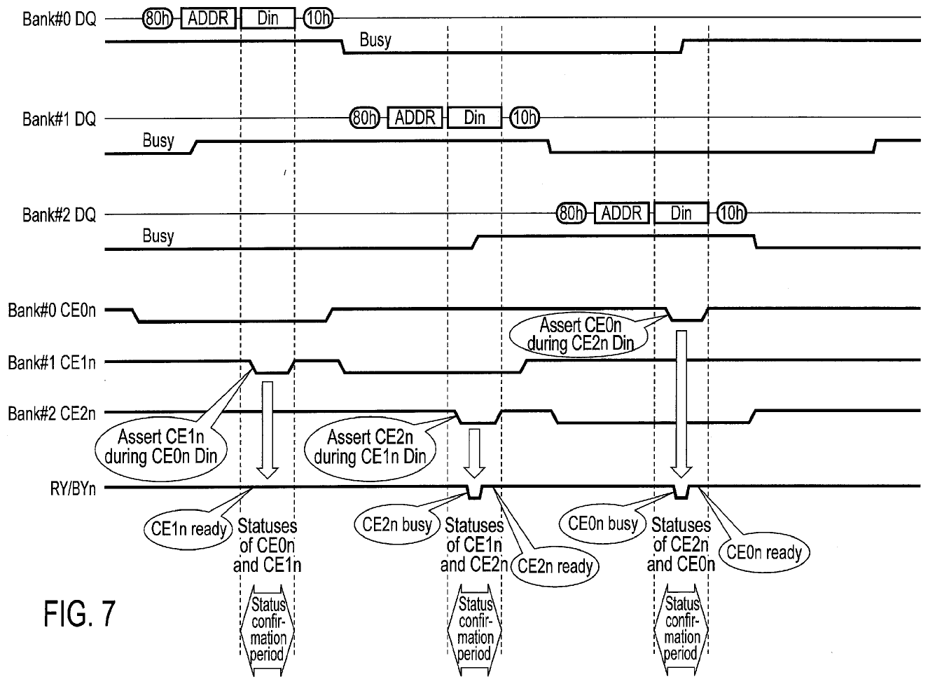

FIG. 7 is a timing chart illustrating the operation of determining the ready/busy status of a check target nonvolatile memory chip whose status is to be checked, by asserting the chip enable signal of the check target nonvolatile memory chip during the period of the data input cycle.

To make it easy to understand, FIG. 7 illustrates the case on the assumption that three nonvolatile memory chips 500 to 502 corresponding to three banks #0 to #2 are connected to the channel Ch.1. In FIG. 7, each command sequence transmitted to the nonvolatile memory chip 500 of the bank #0 is represented as “Bank #0 DQ”, each command sequences transmitted to the nonvolatile memory chip 501 of the bank #1 is represented as “Bank #1 DQ”, and each command sequences transmitted to the nonvolatile memory chip 502 of the bank #2 is represented as “Bank #2 DQ”. Further, the chip enable signal CE corresponding to the bank #0 is represented as “Bank #0 CE0n”, the chip enable signal CE corresponding to the bank #1 is represented as “Bank #1 CE1n”, and the chip enable signal CE corresponding to the bank #2 is represented as “Bank #2 CE2n”.

First, the chip enable signal CE0n corresponding to the nonvolatile memory chip 500 of the bank #0 is asserted, and the program command sequence (command cycle 80h, address cycle ADDR, data input cycle Din and command cycle 10h) for writing data to the nonvolatile memory chip 500 is transmitted to the nonvolatile memory chip 500 of the bank #0 via the data bus of the channel Ch.1.

In the period of the data input cycle Din, while the chip enable signal CE0n is asserted, the chip enable signal CE1n corresponding to the nonvolatile memory chip 501 of the bank #1 is also asserted. While the chip enable signal CE1n corresponding to the nonvolatile memory chip 501 of the bank #1 is being asserted (that is, during the period in which CE1n is at the low level), the status of the ready/busy signal RY/BYn input to the nonvolatile memory control circuit 13 is checked. If the ready/busy signal RY/BYn is at the high-level, it is determined that the nonvolatile memory chip 501 of the bank #1 is in the ready status.

In this case, immediately after the transmission of the program command sequence to the nonvolatile memory chip 500 of the bank #0, a command sequence can be transmitted to the nonvolatile memory chip 501 of the bank #1. The command sequence to be transmitted to the nonvolatile memory chip 501 of the bank #1 may be a program command sequence, a read command sequence or an erase command sequence. FIG. 7 illustrates an example case where a program command sequence is transmitted to the nonvolatile memory chip 501 of the bank #1.

That is, when the transmission of the program command sequence (command cycle 80h, address cycle ADDR, data input cycle Din and command cycle 10h) to the nonvolatile memory chip 500 of the bank #0 is finished, the nonvolatile memory chip 500 of the bank #0 starts the program operation, and is set to the busy status.

The chip enable signal CE0n corresponding to the nonvolatile memory chip 500 of the bank #0 is de-asserted, and in place, the chip enable signal CE1n corresponding to the nonvolatile memory chip 501 of the bank #1 is asserted. Then, the program command sequence (command cycle 80h, address cycle ADDR, data input cycle Din and command cycle 10h) for writing data to the nonvolatile memory chip 501 of the bank #1 is transmitted to the nonvolatile memory chip 501 of the bank #1 via the data bus of the channel Ch.1.

During the period of the data input cycle Din, while the chip enable signal CE1n is asserted, and further the chip enable signal CE2n corresponding to the nonvolatile memory chip 502 of the bank #2 is asserted. While the chip enable signal CE2n corresponding to the nonvolatile memory chip 502 of the bank #2 is being asserted (that is, during the period in which CE2n is at the low level), the status of the ready/busy signal RY/BYn input to the nonvolatile memory control circuit 13 is checked. If the ready/busy signal RY/BYn is at the high-level, it is determined that the nonvolatile memory chip 502 of the bank #2 is in the ready status. FIG. 7 illustrates an example case where, just after the chip enable signal CE2n is asserted, the nonvolatile memory chip 502 of the bank #2 is in the busy status, but while the chip enable signal CE2n is being asserted, the status of the nonvolatile memory chip 502 of the bank #2 changes to the ready status from the busy status.

In this case, immediately after finishing the transmission of the program command sequence to the nonvolatile memory chip 501 of the bank #1, a command sequence can be transmitted to the nonvolatile memory chip 502 of the bank #2. The command sequence to be transmitted to the nonvolatile memory chip 502 of the bank #2 may be a program command sequence, a read command sequence or an erase command sequence. FIG. 7 illustrates an example case that a program command sequence is transmitted to the nonvolatile memory chip 502 of the bank #2.

That is, when the transmission of the program command sequence (command cycle 80h, address cycle ADDR, data input cycle Din and command cycle 10h) to the nonvolatile memory chip 501 of the bank #1 is finished, the nonvolatile memory chip 501 of the bank #1 starts the program operation, and is set in the busy status.

The chip enable signal CE1n corresponding to the nonvolatile memory chip 501 of the bank #1 is de-asserted, and in place, the chip enable signal CE2n corresponding to the nonvolatile memory chip 502 of the bank #2 is asserted. Then, the program command sequence (command cycle 80h, address cycle ADDR, data input cycle Din and command cycle 10h) for writing data to the nonvolatile memory chip 502 of the bank #2 is transmitted to the nonvolatile memory chip 502 of the bank #2 via the data bus of the channel Ch.1.

During the period of the data input cycle Din, the chip enable signal CE0n corresponding to the nonvolatile memory chip 500 of the bank #0 is further asserted while the chip enable signal CE2n is being asserted. While the chip enable signal CE0n corresponding to the nonvolatile memory chip 500 of the bank #0 is being asserted (during the period in which CE0n is at the low level), the status of the ready/busy signal RY/BYn input to the nonvolatile memory control circuit 13 is checked. If the ready/busy signal RY/BYn is at the high-level, it is determined that the nonvolatile memory chip 500 of the bank #0 is in the ready status. FIG. 7 illustrates an example case where, just after the chip enable signal CE0n is asserted, the nonvolatile memory chip 500 of the bank #0 is in the busy status, but while the chip enable signal CE0n is being asserted, the status of the nonvolatile memory chip 500 of the bank #0 changes to the ready status from the busy status.

In this case, immediately after finishing the transmission of the program command sequence to the nonvolatile memory chip 502 of the bank #2, a command sequence can be transmitted to the nonvolatile memory chip 500 of the bank #0. The command sequence to be transmitted to the nonvolatile memory chip 500 of the bank #0 may be a program command sequence, a read command sequence or an erase command sequence.

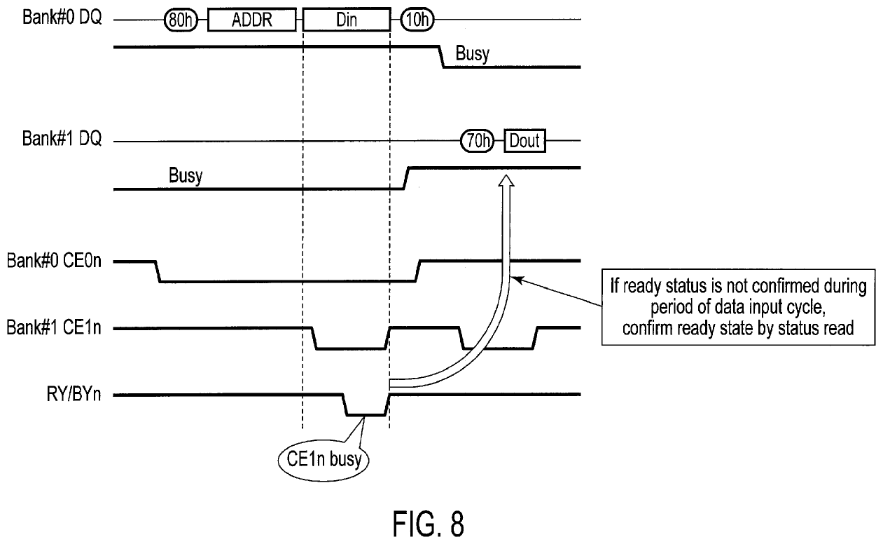

FIG. 8 is a timing chart illustrating the status read operation to be executed when the ready status cannot be confirmed during the period of the data input cycle.

In FIG. 8, each command sequence transmitted to the nonvolatile memory chip 500 of the bank #0 is represented as “Bank #0 DQ”, and each command sequence transmitted to the nonvolatile memory chip 501 of the bank #1 is represented as “Bank #1 DQ”.

First, the chip enable signal CE0n corresponding to the nonvolatile memory chip 500 of the bank #0 is asserted, and the program command sequence (command cycle 80h, address cycle ADDR, data input cycle Din and command cycle 10h) for writing data to the nonvolatile memory chip 500 is transmitted to the nonvolatile memory chip 500 of the bank #0 via the data bus of the channel Ch.1.

During the period of the data input cycle (Din), while the chip enable signal CE0n is being asserted, and the chip enable signal CE1n corresponding to the nonvolatile memory chip 501 of the bank #1 is further asserted. While the chip enable signal CE1n corresponding to the nonvolatile memory chip 501 of the bank #1 is being asserted (that is, during the period in which CE1n is at the low level), the status of the ready/busy signal RY/BYn input to the nonvolatile memory control circuit 13 is checked.

If the nonvolatile memory chip 501 of the bank #1 is executing the program operation corresponding to the program command sequence previously transmitted to the nonvolatile memory chip 501 and the nonvolatile memory chip 501 is thereby in the busy status, the ready/busy signal RY/BYn is in the low level. In this case, it is determined that the nonvolatile memory chip 501 of the bank #1 is in the busy status.

When the transmission of the program command sequence (command cycle 80h, address cycle ADDR, data input cycle Din and command cycle 10h) to the nonvolatile memory chip 500 of the bank #0 is finished, the nonvolatile memory chip 500 of the bank #0 starts the program operation, and is set to the busy status.

After the nonvolatile memory chip 500 of the bank #0 is set in the busy status, the status read operation is started.

In the status read operation, the chip enable signal CE1n corresponding to the nonvolatile memory chip 501 of the bank #1 is asserted, and the status read command (70h) is transmitted to the nonvolatile memory chip 501 of the bank #1 via the data bus of the channel Ch.1. In response to the reception of the status read command (70h), the nonvolatile memory chip 501 outputs its own status (ready status/busy status) to the data bus as a data output (Dout). Thus, the status of the nonvolatile memory chip 501 can be judged once again.

When the nonvolatile memory chip 501 is determined to be in the ready status by the status read operation, the chip enable signal CE1n corresponding to the nonvolatile memory chip 501 of the bank #1 is asserted, and the program command sequence (command cycle 80h, address cycle ADDR, data input cycle Din and command cycle 10h) for writing data to the nonvolatile memory chip 501 is transmitted to the nonvolatile memory chip 501 of the bank #1 via the data bus of the channel Ch.1.

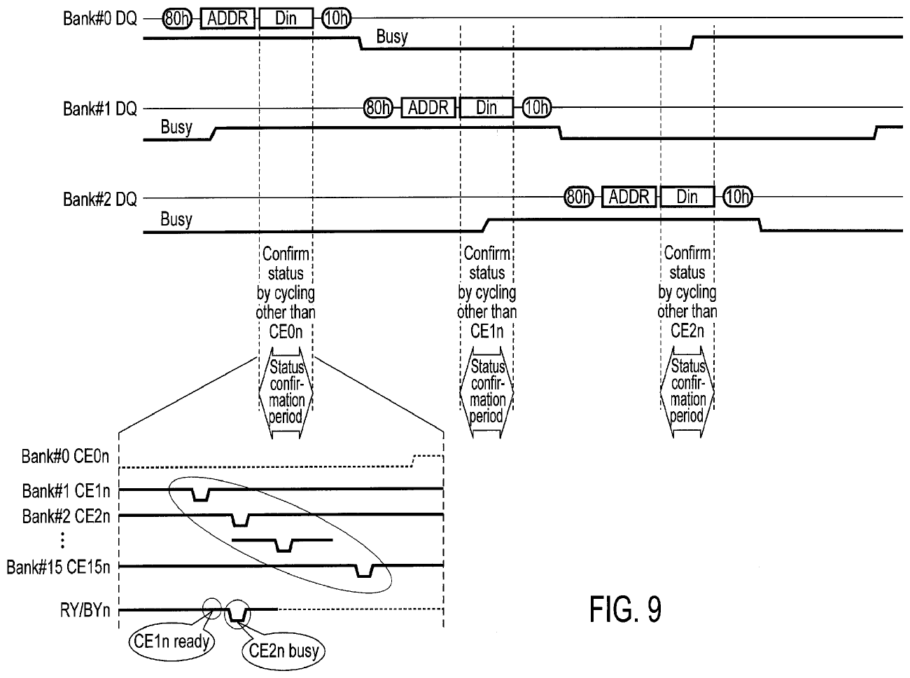

FIG. 9 is a timing chart illustrating the operation of determining whether each of a plurality of nonvolatile memory chips is in the ready status or the busy status during the period of the data input cycle, by alternately asserting the chip enable signals of the nonvolatile memory chips during the period of the data input cycle.

FIG. 9 illustrates the case on the assumption that sixteen nonvolatile memory chips 500 to 515 corresponding to sixteen banks #0 to #15 are connected to the channel Ch.1. Further, In FIG. 9, each command sequence transmitted to the nonvolatile memory chip 500 of the bank #0 is represented as “Bank #0 DQ”, each command sequence transmitted to the nonvolatile memory chip 501 of the bank #1 is represented as “Bank #1 DQ”, and each command sequence transmitted to the nonvolatile memory chip 502 of the bank #2 is represented as “Bank #2 DQ”.

First, the chip enable signal CE0n corresponding to the nonvolatile memory chip 500 of the bank #0 is asserted, and the program command sequence (command cycle 80h, address cycle ADDR, data input cycle Din and command cycle 10h) for writing data to the nonvolatile memory chip 500 is transmitted to the nonvolatile memory chip 500 of the bank #0 via the data bus of the channel Ch.1.

During the period of data input cycle Din, the chip enable signals to be set to the enable state are switched among the chip enable signals CE1n to CE15n excluding the chip enable signal CE0n in order, while the chip enable signal CE0n corresponding to the nonvolatile memory chip 500 of the bank #0 is maintained in the enable state.

More specifically, first, the chip enable signal CE1n corresponding to the nonvolatile memory chip 501 of the bank #1 is asserted. Then, while the chip enable signal CE1n is being asserted (that is, during the period CE1n is at the low level), the status of ready/busy signal RY/BYn input to the nonvolatile memory control circuit 13 is checked and thus it is determined whether or not the nonvolatile memory chip 501 of the bank #1 is in the ready status. FIG. 9 illustrates an example case where the nonvolatile memory chip 501 is in the ready status. In this case, while the chip enable signal CE1n is being asserted (that is, during the period in which CE1n is at the low level), the ready/busy signal RY/BYn input to the nonvolatile memory control circuit 13 is at the high-level.

The assertion period of the chip enable signal CE1n is a second period predetermined so as to be able to confirm the status of each of the fifteen nonvolatile memories during the period of the data input cycle Din.

Next, the chip enable signal CE2n corresponding to the nonvolatile memory chip 502 of the bank #2 is asserted. Then, while the chip enable signal CE2n is being asserted (that is, during the period in which CE2n is at the low level), the status of the ready/busy signal RY/BYn input to the nonvolatile memory control circuit 13 is checked and thus it is determined whether or not the nonvolatile memory chip 502 of the bank #2 is in the ready status. FIG. 9 illustrates an example case where the nonvolatile memory chip 502 is in the busy status. In this case, while the chip enable signal CE2n is being asserted (that is, during the period in which CE2n is at the low level), the ready/busy signal RY/BYn input to the nonvolatile memory control circuit 13 is at the low level. The assertion period of the chip enable signal CE2n is also the second period.

Similarly, the chip enable signal CE3n to the chip enable signal CE14n are asserted in order. The assertion period of each of the chip enable signal CE3n to the chip enable signal CE14n is also the second period.

Lastly, the chip enable signal CE15n corresponding to the nonvolatile memory chip 515 of the bank #15 is asserted. Then, while the chip enable signal CE15n is being asserted (that is, during the period in which CE15n is at the low level), the status of the ready/busy signal RY/BYn input to the nonvolatile memory control circuit 13 is checked and thus it is determined whether or not the nonvolatile memory chip 515 of the bank #15 is in the ready status. The assertion period of the chip enable signal CE15n is also the second period.

As described above, during the period of the data input cycle Din included in the program command sequence for writing data to the nonvolatile memory chip 500 of the bank #0, all the other chip enable signal except the chip enable signal CE0n are asserted alternately. Thus, it is possible to determine whether or not each of all the other nonvolatile memory chips 501 to 515 except the nonvolatile memory chip 500 is in the ready status during the period of the data input cycle (Din).

Therefore, after finishing the transmission of the program command sequence to the nonvolatile memory chip 500 of the bank #0, the transmission of the command sequence (program command sequence, read command sequence or erase command sequence) to any one of one or more nonvolatile memory chips which have been determined to be in the ready status can be immediately started.

FIG. 9 illustrates an example case where a program command sequence is transmitted to the nonvolatile memory chip 501 of the bank #1 determined to be in the ready status.

That is, when the transmission of the program command sequence (command cycle 80h, address cycle ADDR, data input cycle Din and command cycle 10h) to the nonvolatile memory chip 500 of the bank #0 is finished, the nonvolatile memory chip 500 of the bank #0 starts the program operation, and is set to the busy status.

Then, the program command sequence (command cycle 80h, address cycle ADDR, data input cycle Din and command cycle 10h) to write data to the nonvolatile memory chip 501 of the bank #1 is transmitted to the nonvolatile memory chip 501 of the bank #1 through a data bus of channel Ch.1.

During the period of also the data input cycle Din included in the program command sequence for writing data to the nonvolatile memory chip 501 of the bank #1, the other chip enable signals except the chip enable signal CE1n are alternately asserted. In this case, those nonvolatile memory chips which have already been confirmed to be in the ready status are excluded from check target of the status check.

Let us assume the case where, for example, during the period of the data input cycle Din included in the program command sequence for writing data to the nonvolatile memory chip 500 of the bank #0, it is determined that the nonvolatile memory chip 502 of the bank #2 is in the busy status and the nonvolatile memory chip 501 of the bank #1 and the nonvolatile memory chips 503 to 515 of the banks #3 to bank #15 are in the ready status.

In this case, during the period of the data input cycle (Din) included in the program command sequence for writing data to the nonvolatile memory chip 501 of the bank #1, the nonvolatile memory chips 503 to 515 of the bank #3 to bank #15, data are excluded from the check target of the status check. Then, during the period of the data input cycle Din, the chip enable signal CE0n corresponding to the nonvolatile memory chip 500 of the bank #0 and the chip enable signal CE2n corresponding to the nonvolatile memory chip 502 of the bank #2 are alternately asserted.

Thus, the current status of the nonvolatile memory chip 500 of the bank #0, whose ready status has not yet been confirmed and the current status of nonvolatile memory chip 502 of the bank #2, whose ready status has not yet been confirmed can be determined.

After finishing the transmission of the program command sequence to the nonvolatile memory chip 501 of the bank #1, the command sequence (program command sequence, read command sequence or erase command sequence) to any one nonvolatile memory chip which has been already confirmed to be in the ready status can be immediately started.

FIG. 9 illustrates an example case where it is determined that the nonvolatile memory chip 502 of the bank #2 is in the ready status, and a program command sequence is transmitted to the nonvolatile memory chip 502 of the bank #2.

That is, when the transmission of the program command sequence (command cycle 80h, address cycle ADDR, data input cycle Din and command cycle 10h) to the nonvolatile memory chip 501 of the bank #1 is finished, the nonvolatile memory chip 501 of the bank #1 starts the program operation, and is set to the busy status.

Then, the program command sequence (command cycle 80h, address cycle ADDR, data input cycle Din and command cycle 10h) for writing data to the nonvolatile memory chip 502 of the bank #2 is transmitted to the nonvolatile memory chip 502 of the bank #2 via the data bus of the channel Ch.1.

During also the period of the data input cycle Din included in the program command sequence for writing data to the nonvolatile memory chip 502 of the bank #2, the other chip enable signals except the chip enable signal CE2n is alternately asserted. In this case, those nonvolatile memory chips which have already confirmed to be in the ready status are excluded from the check target of the status check.

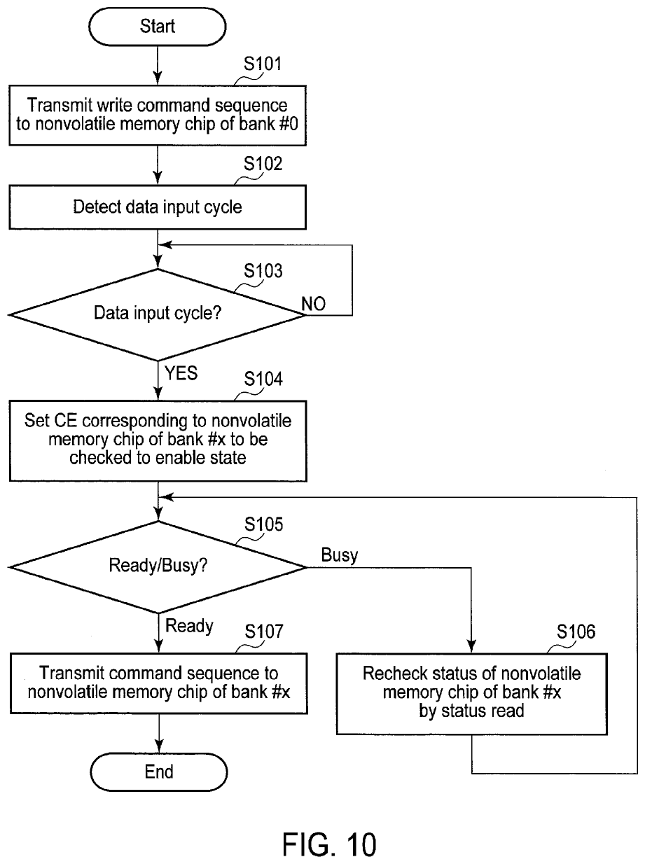

FIG. 10 is a flow chart illustrating the procedure of the process of determining the ready/busy status of a check target nonvolatile memory chip by asserting the chip enable signal of the check target nonvolatile memory chip during the period of the data input cycle.

The nonvolatile memory control circuit 13 of the controller 4, transmits, for example, a program command sequence for writing data to the nonvolatile memory chip 500 of the bank #0 to the nonvolatile memory chip 500 of the bank #0 via the channel Ch.1 (step S101).

In step S101, if the chip enable signal CE0n corresponding to the nonvolatile memory chip 500 of the bank #0 is in the disable state, the nonvolatile memory control circuit 13, first, sets the chip enable signal CE0n to the enable state, and then transmits a program command sequence for writing data to the nonvolatile memory chip 500 of the bank #0 to the nonvolatile memory chip 500 of the bank #0 via the channel Ch.1.

The status determining circuit 131 of the nonvolatile memory control circuit 13 detects the start of the data input cycle included in the program command sequence using the data input cycle detection circuit 201 (step S102).

When the status determining circuit 131 detects the start of the data input cycle (YES in step S103), the status determining circuit 131 sets the chip enable signal corresponding to the nonvolatile memory chip of a bank (bank #x) to be checked to the enable state while maintaining the chip enable signal CE0n corresponding to the nonvolatile memory chip 500 of the bank #0 in the enable state, using the chip enable assertion/de-assertion circuit 202 (step S104). The bank to be checked is a bank whose status should be checked. The bank to be checked is a bank which belongs to the channel Ch.1 and is different from the bank #0.

The status determining circuit 131 determines whether the nonvolatile memory chip of a bank #x to be checked is in the ready status by checking the status of the ready/busy signal RY/BYn input to the ready/busy signal RY/BYn terminal of the nonvolatile memory control circuit 13 while the chip enable signal corresponding to the nonvolatile memory chip of the bank #x to be checked is in the enable state (step S105).

When it is determined that the nonvolatile memory chip of the bank #x to be checked is in the ready status (Ready in step S105), the nonvolatile memory control circuit 13 transmits the command sequence to the nonvolatile memory chip of the bank #x to be checked to the nonvolatile memory chip of the bank #x to be checked in response to the end of the transmission of the program command sequence to the nonvolatile memory chip 500 of the bank #0 via the channel Ch.1 (step S107).

If it is not determined that the nonvolatile memory chip of the bank #x to be checked is in the ready status (Busy in step S105), the status determining circuit 131 of the nonvolatile memory control circuit 13 checks once again whether or not the nonvolatile memory chip of the bank #x to be checked is in the ready status using the status read control circuit 203 (step S106).

In step S106, the status determining circuit 131 transmits a status read command to the nonvolatile memory chip of the bank #x via the channel Ch.1 in response to the end of the transmission of the program command sequence to the nonvolatile memory chip 500 of the bank #0, and determines once again whether or not the nonvolatile memory chip of the bank #x is in the ready status. Here, when it is thus determined that the nonvolatile memory chip of the bank #x to be checked is in the ready status (Ready in step S105), the nonvolatile memory control circuit 13 transmits a command sequence to the nonvolatile memory chip of the bank #x to be checked to the nonvolatile memory chip of the bank #x to be checked via the channel Ch.1 (step S107). Then, the nonvolatile memory control circuit 13 finishes the process (End).

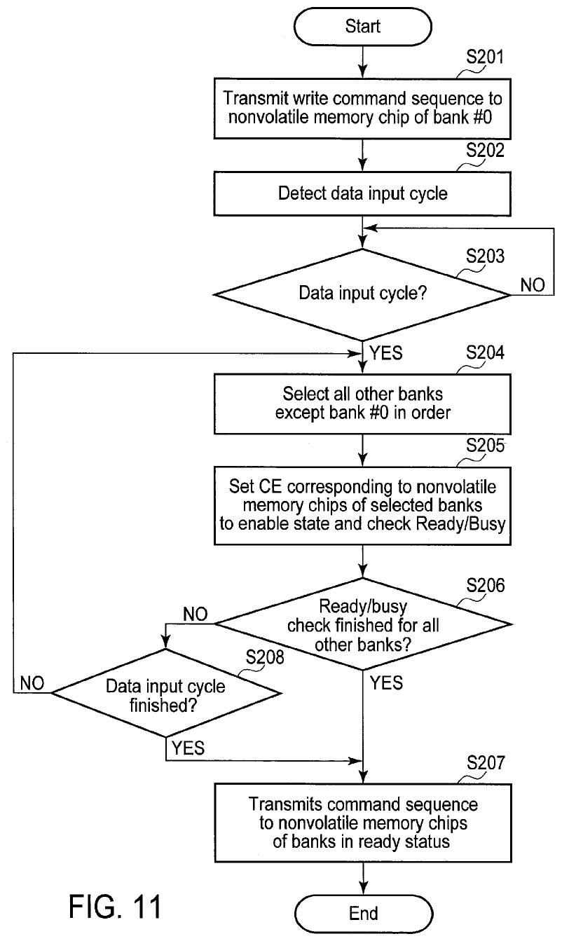

FIG. 11 is a flow chart illustrating the procedure of the process of determining the ready/busy statuses of a plurality of nonvolatile memory chips by asserting the chip enable signals of the nonvolatile memory chips alternately during the period of the data input cycle.

The nonvolatile memory control circuit 13 of controller 4 transmits, for example, a program command sequence for writing data to the nonvolatile memory chip 500 of the bank #0 to the nonvolatile memory chip 500 of the bank #0 via the channel Ch.1 (step S201).

In step S201, if the chip enable signal CE0n corresponding to the nonvolatile memory chip 500 of the bank #0 is in the disable state, the nonvolatile memory control circuit 13, first, sets the chip enable signal CE0n to the enable state and transmits a program command sequence for writing data to the nonvolatile memory chip 500 of the bank #0 to the nonvolatile memory chip 500 of the bank #0 via the channel Ch.1.

The status determining circuit 131 of the nonvolatile memory control circuit 13 detects the start of the data input cycle included in the program command sequence using the data input cycle detection circuit 201 (step S202).

If the status determining circuit 131 detects the start of the data input cycle (YES in step S203), the status determining circuit 131 selects all the other banks except the bank #0 in order as the banks to be checked (step S204). In the process of selecting the banks to be checked in order, the status determining circuit 131 may select, for example, the banks to be checked in an ascending order as the bank #1, bank #2, . . . , bank #15, or in a descending order as the bank #15, bank #14, . . . , bank #2. Further, note that even there are sixteen banks, the bank #0 to bank #15, the nonvolatile memory chip corresponding to the respective bank may not necessarily be connected to the channel Ch.1 (or the power of the nonvolatile memory chip corresponding to the respective bank may not necessarily be on). In this case, the status determining circuit 131 may exclude those banks whose nonvolatile memory chips are not connected to the channel Ch.1 (or banks the power of whose corresponding nonvolatile memory chips is off) and select a bank to be checked in order, from the remaining banks.

The status determining circuit 131 asserts the chip enable signal corresponding to the nonvolatile memory chip of the selected bank and determines the ready/busy status of the nonvolatile memory chip (step S205).

More specifically, in step S205, the status determining circuit 131 sets the chip enable signal corresponding to the nonvolatile memory chip of the selected bank to the enable state while maintaining the chip enable signal CE0n corresponding to the nonvolatile memory chip 500 of the bank #0 in the enable state using the chip enable assertion/de-assertion circuit 202 (1), and determines whether or not the nonvolatile memory chip of the selected bank is in the ready status by checking the status of the ready/busy signal RY/BYn input to the ready/busy signal RY/BYn terminal of the nonvolatile memory control circuit 13 during the period in which the chip enable signal is in the enable state (2).

Until the checking all the other banks except the bank #0 in terms the ready/busy status is finished, the status determining circuit 131 repeats the execution of the processes of step S204 and step S205. The timing of the execution of the process of step S204 can be automatically controlled by setting a timer.

Each time the process of step S204 is executed, the status determining circuit 131 switches the chip enable signal to be set to the enable state among other chip enable signals except the chip enable signal CE0n in order using the chip enable assertion/de-assertion circuit 202. Then, in step S205, the status determining circuit 131 checks the status of the ready/busy signal input during the period in which the chip enable signal is in the enable state, and determines whether or not the nonvolatile memory chip corresponding to the chip enable signal which is in the enable state is in the ready status.

When the checking of all the other banks except the bank #0 as to the ready/busy state is finished (YES in step S206), the nonvolatile memory control circuit 13 transmits a command sequence to any one of nonvolatile memory chips determined to be in the ready status to the any one of the nonvolatile memory chips via the channel in response to the end of the transmission of the program command sequence to the nonvolatile memory chip 500 of the bank #0 (step S207). Then, the nonvolatile memory control circuit 13 finishes the process (End).

If the checking of all the other banks except the bank #0 in terms the ready/busy status is not yet finished (NO in step S206), the nonvolatile memory control circuit 13 determines whether or not the data input cycle is finished (step S208).

If the data input cycle is not finished (NO in step S208), the nonvolatile memory control circuit 13 executes the processes of step S204 and step S205 again. When the data input cycle is finished (YES in step S208), the nonvolatile memory control circuit 13 advances to the process of step S207, and transmits the command sequence to any one of nonvolatile memory chips determined to be in the ready status to the any one of the nonvolatile memory chips through the channel. Then, the nonvolatile memory control circuit 13 finishes the process (End).

As discussed above, according to this embodiment, the nonvolatile memory control circuit 13 included in the controller 4 detects a program command sequence and sets the chip enable signal corresponding to a nonvolatile memory chip to be checked in the enable state during the period of at least the data input cycle in the detected program command sequence. Thus, in such a structure that a plurality of ready/busy signal RY/BYn terminals respectively corresponding to the nonvolatile memory chips 500 to 515 are commonly connected to one ready/busy signal RY/BYn terminal of the nonvolatile memory control circuit 13, the nonvolatile memory control circuit 13 can determine whether or not the nonvolatile memory chip to be checked is in the ready status by checking the status of the ready/busy signal input to the nonvolatile memory control circuit 13 during the period in which the chip enable signal corresponding to the nonvolatile memory chip to be checked is in the enable state.

Therefore, as compared to the configuration to determine whether or not each nonvolatile memory chip is in the ready status using only the status read operation, the time period in which a channel is occupied for status check can be reduced.

Further, when it is indicated that a ready/busy signal input to the nonvolatile memory control circuit 13 is in the ready status during the period in which the chip enable signal corresponding to a nonvolatile memory chip to be checked is in the enable state, the nonvolatile memory control circuit 13 transmits a command sequence to the nonvolatile memory chip to be checked in response to the end of the program command sequence. Therefore, as compared to the configuration to start the checking of the status (ready/busy status) of the nonvolatile memory chip to be checked after the end of a program command sequence, the command sequence can be transmitted at an earlier timing.

Thus, the performance of writing of data and reading of data can be improved.

In the embodiment, a NAND flash memory is discussed as an example of the nonvolatile memory. But, the function of the present embodiment can be applied to other various nonvolatile memories such as magnetoresistive random access memory (MRAM), phase change random access memory (PRAM), resistive random access memory (ReRAM) and ferroelectric random access memory (FeRAM).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising a plurality of nonvolatile memory chip and a controller configured to control the plurality of nonvolatile memory chips via a channel,
the controller having a first terminal commonly connected to a plurality of ready/busy signal terminals of the plurality of nonvolatile memory chips and a plurality of second terminals which supply a plurality of chip enable signals to the plurality of nonvolatile memory chips, respectively, each of the plurality of nonvolatile memory chips outputting a ready/busy signal only in a period in which a corresponding chip enable signal is in an enable state, wherein
the controller is configured to:
transmit a program command sequence to write data to a first nonvolatile memory chip of the plurality of nonvolatile memory chips to the first nonvolatile memory chip via the channel;
detect the program command sequence and set, while maintaining a first chip enable signal corresponding to the first nonvolatile memory chip in an enable state, a second chip enable signal corresponding to a second nonvolatile memory chip of the plurality of nonvolatile memory chips to an enable state during a period of at least a data input cycle of the detected program command sequence; and
transmit, when it is indicated that a ready/busy signal input to the first terminal is in a ready status while the second chip enable signal is in the enable state, a command sequence for the second nonvolatile memory chip to the second nonvolatile memory chip via the channel in response to end of the transmission of the program command sequence.

2. The memory system of claim 1, wherein
the controller is configured to:
detect start of the data input cycle as the program command sequence; and
set the second chip enable signal in the enable state while maintaining the first chip enable signal in the enable state in response to detection of the start of the data input cycle.

3. The memory system of claim 2, wherein
the controller is configured to maintain the second chip enable signal in the enable state only for a first period to as to set the second chip enable signal in a disable state before end of the data input cycle.

4. The memory system of claim 1, wherein
the command sequence for the second nonvolatile memory chip is a program command sequence, a read command sequence or an erase command sequence.

5. The memory system of claim 1, wherein
the controller is configured to:
when it is not indicated that the ready/busy signal input to the first terminal is in the ready status while the second chip enable signal is in the enable state,
transmit a status read command to the second nonvolatile memory chip via the channel in response to the end of the transmission of the program command sequence; and
determine once again whether or not the second nonvolatile memory chip is in the ready status.

6. The memory system of claim 1, wherein
the controller is configured to:
during the period of at least the data input cycle in the program command sequence, switch a chip enable signal to be set to the enable state among other chip enable signals except the first chip enable signal in order while maintaining the first chip enable signal in the enable state; and
determine whether or not each of the other nonvolatile memory chips except the first nonvolatile memory chip is in the ready status by checking the status of the ready/busy signal input to the first terminal while each of the other chip enable signals is in the enable state.

7. A method of controlling a memory system comprising a plurality of nonvolatile memory chips and a controller configured to control the plurality of nonvolatile memory chips via a channel,
the controller having a first terminal commonly connected to a plurality of ready/busy signal terminals of the plurality of nonvolatile memory chips and a plurality of second terminals which supply a plurality of chip enable signals to the plurality of nonvolatile memory chips, respectively, each of the plurality of nonvolatile memory chips outputting a ready/busy signal only in a period in which a corresponding chip enable signal is in an enable state,
the method comprising:
transmitting a program command sequence to write data to a first nonvolatile memory chip of the plurality of nonvolatile memory chips to the first nonvolatile memory chip via the channel;
detecting the program command sequence and setting, while maintaining a first chip enable signal corresponding to the first nonvolatile memory chip in an enable state, a second chip enable signal corresponding to a second nonvolatile memory chip of the plurality of nonvolatile memory chips to the enable state during a period of at least a data input cycle of the detected program command sequence; and
transmitting, when it is indicated that a ready/busy signal input to the first terminal is in a ready status while the second chip enable signal is in the enable state, a command sequence for the second nonvolatile memory chip to the second nonvolatile memory chip via the channel in response to end of the transmission of the program command sequence.

8. The method of claim 7, wherein
the setting the second chip enable signal to the enable state includes:
detecting start of the data input cycle as the program command sequence; and
setting the second chip enable signal to the enable state while maintaining the first chip enable signal in the enable state in reply to the detecting of the start of the data input cycle.

9. The method of claim 7, further comprising:
when it is not indicated that the ready/busy signal input to the first terminal is in the ready status while the second chip enable signal is in the enable state,
transmitting a status read command to the second nonvolatile memory chip via the channel in response to the end of the transmission of the program command sequence; and
determining once again whether or not the second nonvolatile memory chip is in the ready status.

10. The method of claim 7, further comprising:
during the period of at least the data input cycle in the program command sequence, switching a chip enable signal to be set to the enable state among other chip enable signals except the first chip enable signal in order while maintaining the first chip enable signal in the enable state; and
determining whether or not each of the other nonvolatile memory chips except the first nonvolatile memory chip is in the ready status by checking the status of the ready/busy signal input to the first terminal while each of the other chip enable signals is in the enable state.
